(19) United States
(12) Patent Application Publication
(10) Pub. No.: US 2013/0083267 A1
(43) Pub. Date: Apr. 4, 2013

(54) ASSEMBLING METHOD AND STRUCTURE FOR LIQUID CRYSTAL DISPLAY DEVICE, LIQUID CRYSTAL PANEL AND BACKLIGHT MODULE

(71) Applicant: Ge-Ge Zhou, Shenzhen (CN)

(72) Inventor: Ge-Ge Zhou, Shenzhen (CN)

(21) Appl. No.: 13/376,793

(22) PCT Filed: Sep. 30, 2011
(86) PCT No.: PCT/CN11/80430

§ 371 Date: Dec. 7, 2011

(51) Int. Cl. G02F 1/1333; B29C 65/50; H05K 13/04

(52) U.S. Cl. 349/58; 29/592.1; 156/60

(57) ABSTRACT

An assembling method and structure for a liquid crystal display device, a liquid crystal panel and a backlight module. The assembling method includes disposing a front frame, disposing of a back cover in corresponding to the front frame to form an accommodation space by the front frame and the back cover, disposing a liquid crystal panel at a forefront of the accommodation space, disposing a backlight module inside the accommodation space behind the liquid crystal panel, further including disposing a strip, so that the liquid crystal panel is supported by a first side of the strip, and a second side of the strip opposite to the first side is supported on an inner side of the back cover.

### FIELD OF THE INVENTION

The present invention relates to a liquid crystal display device, and more particularly to an assembling of a liquid crystal panel and a backlight module of a liquid crystal display device.

### BACKGROUND OF THE INVENTION

Liquid crystal display device employs liquid crystal for displaying pictures or graphic, and it is usually composed of liquid crystal panel, backlight module, related digital circuit and power. In order to fulfill the requirements of slimness and lightness, the liquid crystal panel and the backlight module have to be matched up with each other properly; generally, the liquid crystal panel and the backlight module are assembled together. For instance, Chinese publication No. CN100582887C discloses a liquid crystal display which comprises a backlight module, a liquid crystal panel, a front frame, a first limitation element and a second limitation element. A plastic frame is disposed on a back plate of the backlight module, and the liquid crystal panel is disposed between the plastic frame and the front frame. There is another conventional assembling structure for liquid crystal panel and backlight module. Referring to FIG. 1, it mainly comprises a front frame 1, a back cover 2 in corresponding to the front frame 1, a liquid crystal panel 3 is disposed at a forefront of an accommodating space formed between the front frame 1 and the back cover 2, a light bar 4, a light guide plate 5 is disposed beside the light bar 4, an optical film 6 is disposed over a light emitting surface of the light guide plate 5, and a middle frame 7. The front frame 1, the middle frame 7 and the back cover 2 have different functions; all the components are supported by the back cover 2 and it can also ensure flatness of a backlight module; the liquid crystal panel 3 is supported by the middle frame 7, the optical film 6 and the light guide plate 5 are fixed by it, and a certain amount of light can be blocked from leaking out by the middle frame 7; the liquid crystal panel 3 is fixed by the front frame 1 and is prevented from bouncing off from its position.

The conventional assembling method and structure for liquid crystal panel and backlight module requires plastic frame and middle frame, the molding expenses for the plastic and middle frames will increase the total costs, and the assembling procedures are rather troublesome and slow.

### SUMMARY OF THE INVENTION

The present invention relates to a liquid crystal display device and more particularly to an assembling of a liquid crystal panel and a backlight module of a liquid crystal display device.

The present invention provides an assembling method and structure for a liquid crystal panel and a backlight module in order to tackle the abovementioned technical problems, so that the costs can be reduced, and convenient and fast assembling procedures are enabled.

Technical projects employed by the present invention to tackle the abovementioned technical problems include: providing an assembling method for a liquid crystal panel and a backlight module, it includes disposing of a front frame, disposing of a back cover in corresponding to the front frame to form an accommodation space enclosed by the front frame and the back frame, disposing of a liquid crystal panel at a forefront of the accommodation space, disposing of a backlight module inside the accommodation space behind the liquid crystal panel, further includes disposing of a strip, so that the liquid crystal panel is supported by a first side of the strip, and a second side of the strip opposite to the first side is supported on an inner side of the back cover.

Furthermore, the technical projects employed by the present invention to tackle the abovementioned technical problems further include; providing an assembling structure for a liquid crystal panel and a backlight module, it comprises a front frame, a back cover in corresponding to the front frame to form an accommodation space enclosed by the front frame and the back cover, a liquid crystal panel is disposed inside the accommodation space at a forefront, a backlight module is disposed inside the accommodation space behind the liquid crystal panel, further comprises a strip, the liquid crystal panel is supported by a first side of the strip, a second side of the strip opposite to the first side is supported on an inner side of the back cover.

Furthermore, the technical projects employed by the present invention to tackle the abovementioned technical problems further include; providing a liquid crystal display device, it comprises a front frame, a back cover in corresponding to the front frame to form an accommodation space enclosed by the front frame and the back cover, a liquid crystal panel is disposed inside the accommodation space at a forefront, a backlight module is disposed inside the accommodation space behind the liquid crystal panel, further comprises a strip, the liquid crystal panel is supported by a first side of the strip, a second side of the strip opposite to the first side is supported on an inner side of the back cover.

In comparing to conventional techniques, an assembling method and structure for a liquid crystal display device, a liquid crystal panel and a backlight module of the present invention can reduce costs and enable convenient and fast assembling procedures by employing a strip instead of plastic frame and middle frame.

### BRIEF DESCRIPTION OF THE DRAWINGS

FIG. 1 is an exploded perspective view of an assembling structure of a liquid crystal panel and a backlight module of a prior art;

FIG. 2 is an exploded perspective view of an assembling structure of a liquid crystal panel and a backlight module of the present invention; and

FIG. 3 is a cross-sectional view of an assembling structure of a liquid crystal panel and a backlight module of the present invention.

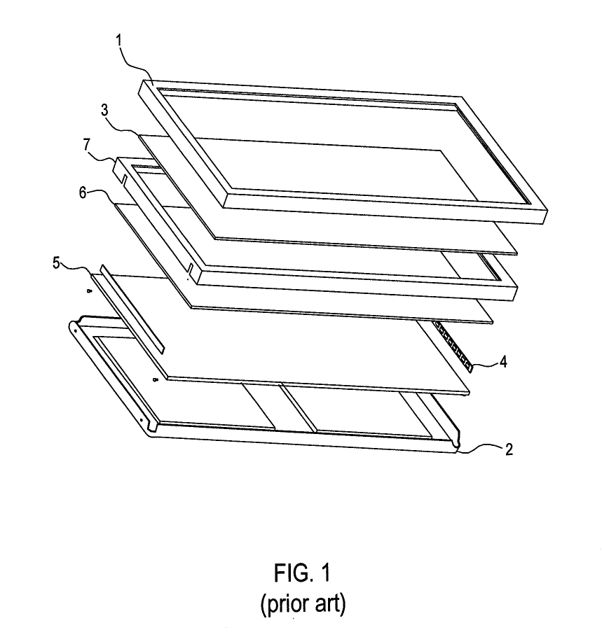

### DETAILED DESCRIPTION OF THE INVENTION

The present invention will become more fully understood by reference to the following detailed description of a preferred embodiment thereof when read in conjunction with the attached drawings.

An assembling method for a liquid crystal panel and a backlight module of the present invention is achieved by employing a strip to support a liquid crystal panel, a side of the strip is supported on the inner side of the back cover, and the liquid crystal panel is supported by an opposite side of the strip. More specifically, the strip can be adhered on a light guide plate; or, the strip can be adhered on an optical film; or, the strip can be adhered directly on the back cover. Preferably, the strip is made of rubber. By employing this assembling method, plastic frame and middle frame of conventional technique can be omitted, convenient and fast assembling is enabled and the costs are reduced without compromising dependability.

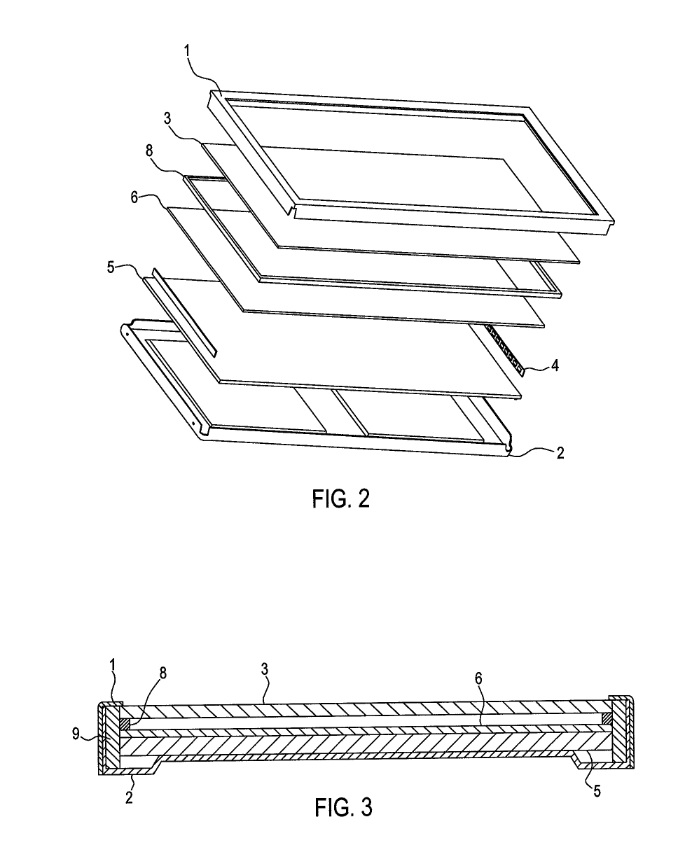

Referring to FIGS. 2 and 3, they show an embodiment of an assembling structure for a liquid crystal panel and a backlight module of the present invention embodied by applying an assembling method of the present invention, mainly comprises a front frame 1, a back cover 2 in corresponding to the front frame 1 to form an accommodation space enclosed by the front frame 1 and the back cover 2, a liquid crystal panel 3 is disposed inside the accommodation space at a forefront, a backlight module is disposed inside the accommodation space behind the liquid crystal panel 3. The backlight module comprises a light bar 4, a light guide plate 5, an optical film 6, and a strip 8; the liquid crystal panel 3 is supported by a first side (front side) of the strip 8, a second side (back side) of the strip 8 opposite to the first side is supported on an inner side of the back cover 2. More specifically, a back side of the light guide plate 5 is supported on the inner side of the back cover 2, a back side of the optical film 6 is adhered with a front side of the light guide plate 5, and the second side (back side) of the strip 8 is adhered on the front side of the optical film 6. In the embodiment of an assembling structure of the present invention, further comprises a blocking piece 9 disposed at an edge of the accommodation space in order to enhance fixation of the liquid crystal panel 3 and the backlight module. A front side of the blocking piece 9 is pressed against an inner side of the front frame 1, and a back side of the blocking piece 9 is pressed against the inner side of the back cover 2. A middle portion of the inner side of the back cover 2 is structurally indented, so that the backlight module can be matched up flatly with the liquid crystal panel 3.

It is necessary to mention that, in another embodiment, the optical film 6 can be omitted, or sizes of the optical film 6 are smaller than those of the light guide plate 5, so that edges of the light guide plate 5 are not blocked by the optical film 6. The second side (back side) of the strip 8 can be directly adhered on the front side of the light guide plate 5. In another embodiment, sizes of the light guide plate 5 can be smaller than those of the inner side of the back cover 2, so that edges of the inner side of the back cover 2 are not blocked by light guide plate 5, and the second side (back side) of the strip 8 can be directly adhered on the inner side of the back cover 2.

A liquid crystal display device of the present invention is made according to the abovementioned assembling method, wherein the abovementioned assembling structure for the liquid crystal panel and the backlight module can be included.

When an assembling method and structure for a liquid crystal display device, a liquid crystal panel and a backlight module of the present invention is employed to assemble the liquid crystal panel 3 and the backlight module together, simply using adhesive on the back side of the strip 8, then the back side with the adhesive can be adhered on the optical film 6 disposed on the light guide plate 5; or, can be adhered directly on the light guide plate 5; or, can be adhered directly on the inner side of the back cover 2; the front side of the strip 8 is used to support the liquid crystal panel 3, and the liquid crystal panel 3 is fixed on its edges by the blocking piece 9, and finally the liquid crystal panel 3 is further fixed by covering with the front frame 1 on its top.

Note that the specifications relating to the above embodiments should be construed as exemplary rather than as limitative of the present invention, with many variations and modifications being readily attainable by a person of average skill in the art without departing from the spirit or scope thereof as defined by the appended claims and their legal equivalents.

What is claimed is:

1. An assembling method for a liquid crystal panel and a backlight module comprising:
disposing a front frame;
disposing a back cover in corresponding to the front frame to form an accommodation space enclosed by the front frame and the back cover;
disposing a liquid crystal panel at a forefront of the accommodation space;
disposing a backlight module inside the accommodation space behind the liquid crystal panel; and
disposing a strip, so that the liquid crystal panel is supported by a first side of the strip, and a second side of the strip opposite to the first side is supported on an inner side of the back cover.

2. The assembling method as claimed in claim 1, wherein the backlight module comprises a light guide plate, having a back side of the light guide plate supported on the inner side of the back cover, and the second side of the strip adhered on a front side of the light guide plate; or, the backlight module comprises a light guide plate and an optical film, having a back side of the light guide plate supported on the inner side of the back cover, a back side of the optical film adhered with a front side of the light guide plate, and the second side of the strip adhered on a front side of the optical film; or, having the second side of the strip adhered on the inner side of the back cover.

3. The assembling method as claimed in claim 1, further comprising disposing a blocking piece at an edge of the accommodation space.

4. The assembling method as claimed in claim 1, wherein the second side of the strip is adhesive.

5. An assembling structure for a liquid crystal panel and a backlight module comprising:
a front frame;
a back cover in corresponding to the front frame to form an accommodation space enclosed by the front frame and the back cover;
a liquid crystal panel disposed inside the accommodation space at a forefront;
a backlight module disposed inside the accommodation space behind the liquid crystal panel; and
a strip, the liquid crystal panel is supported by a first side of the strip, a second side of the strip opposite to the first side is supported on an inner side of the back cover.

6. The assembling structure as claimed in claim 5, wherein the backlight module comprises a light guide plate, a back side of the light guide plate is supported on the inner side of the back cover, and the second side of the strip is adhered on a front side of the light guide plate; or, the backlight module comprises a light guide plate and an optical film, a back side of the light guide plate is supported on the inner side of the back cover, a back side of the optical film is adhered with a front side of the light guide plate, and the second side of the strip is adhered on a front side of the optical film; or, the second side of the strip is adhered on the inner side of the back cover.

7. The assembling structure as claimed in claim 5, further comprising a blocking piece disposed on an edge of the accommodation space.

8. The assembling structure as claimed in claim 5, wherein the second side of the strip is adhesive.

9. A liquid crystal display device comprising:
a front frame;
a back cover in corresponding to the front frame to form an accommodation space enclosed by the front frame and the back cover;
a liquid crystal panel disposed inside the accommodation space at a forefront;
a backlight module disposed inside the accommodation space behind the liquid crystal panel; and
a strip, the liquid crystal panel is supported by a first side of the strip, a second side of the strip opposite to the first side is supported on an inner side of the back cover.

10. The liquid crystal display device as claimed in claim 9, wherein the second side of the strip is adhesive, the backlight module comprises a light guide plate, a back side of the light guide plate is supported on the inner side of the back cover, and the second side of the strip is adhered on a front side of the light guide plate; or, the backlight module comprises a light guide plate and an optical film, a back side of the light guide plate is supported on the inner side of the back cover, a back side of the optical film is adhered with a front side of the light guide plate, and the second side of the strip is adhered on a front side of the optical film; or, the second side of the strip is adhered on the inner side of the back cover.
